(19) United States
(12) Patent Application Publication
(10) Pub. No.: US 2025/0201765 A1
(43) Pub. Date: Jun. 19, 2025

(54) METHODS OF OPERATING WIRE BONDING SYSTEMS, INCLUDING METHODS OF DETECTING AND/OR PREVENTING WIRE FLY-OUT ON SUCH SYSTEMS

(71) Applicant: Kulicke and Soffa Industries, Inc., Fort Washington, PA (US)

(72) Inventors: Gary Gillotti, North Wales, PA (US); Racheli Herskowits, Philadelphia, PA (US); Stephen Babinetz, Lansdale, PA (US)

(73) Assignee: Kulicke and Soffa Industries, Inc., Fort Washington, PA (US)

(21) Appl. No.: 18/976,561

(22) Filed: Dec. 11, 2024

Related U.S. Application Data
(60) Provisional application No. 63/610,501, filed on Dec. 15, 2023.

(51) Int. Cl. H01L 23/00; H01L 21/66

(52) U.S. Cl. CPC H01L 24/85; H01L 22/12; H01L 24/78; H01L 2224/78901; H01L 2224/859

(57) ABSTRACT

A method of operating a wire bonding system is provided. The method includes the steps of: (a) forming a wire bond between (i) a portion of wire and (ii) a bonding location of a workpiece using a wire bonding tool; and (b) detecting if the portion of wire separates from a wire supply during step (a).

### CROSS REFERENCE TO RELATED APPLICATION

This application claims the benefit of U.S. Provisional Application No. 63/610,501, filed on Dec. 15, 2023, the content of which is herein incorporated by reference.

### FIELD

The invention relates to methods of operating wire bonding systems, and more particularly, to methods of early error detection detecting and/or preventing wire fly out on such systems.

### BACKGROUND

In the processing and packaging of semiconductor devices, wire bonding continues to be a primary method of providing electrical interconnection between two or more locations within a package (e.g., between a die pad of a semiconductor die and a lead of a leadframe). More specifically, using a wire bonder (also known as a wire bonding system) wire loops are formed between respective locations to be electrically interconnected. The primary methods of forming wire loops are ball bonding and wedge bonding. In forming the bonds between (a) the ends of the wire loop and (b) the bond site (e.g., a die pad, a lead, etc.), varying types of bonding energy may be used, for example, ultrasonic energy, thermosonic energy, thermocompressive energy, amongst others. Wire bonding machines (e.g., stud bumping machines) are also used to form conductive bumps from portions of wire.

When forming certain types of wire bonds (e.g., stitch bonds of a wire loop), early separation between (i) the bonded portion of wire and (ii) the wire supply may occur. Thus, it would be desirable to provide improved methods of operating wire bonding systems, including to address such potential early separation.

### SUMMARY

According to an exemplary embodiment of the invention, a method of operating a wire bonding system is provided. The method includes the steps of: (a) forming a wire bond between (i) a portion of wire and (ii) a bonding location of a workpiece using a wire bonding tool; and (b) detecting if the portion of wire separates from a wire supply during step (a).

According to other embodiments of the invention, the method recited in the immediately preceding paragraph may have any one or more of the following features: the wire bond formed in step (a) is a stitch bond of a wire loop; the wire bond formed in step (a) is a first bond of a wire loop; the wire bond formed in step (a) is a conductive bump; step (b) includes using a detection system to detect if the portion of wire separates from the wire supply during step (a); the detection system monitors electrical continuity between the portion of wire and the wire supply during step (b); the detection system monitors impedance between the portion of wire and the wire supply during step (b); the detection system is electrically coupled to the wire supply such that the detection system is configured to detect if the portion of wire separates from the wire supply during step (a); further including a step of (c) closing a wire clamp to secure another portion of wire from the wire supply if the portion of wire is separated from the wire supply during step (a); step (c) stops the another portion of wire from being pulled through the wire bonding tool due to tension being applied to the another portion of wire; and/or further including a step of (d) providing a wire tail with an end portion of the wire supply below a working end of the wire bonding tool after step (c).

According to another exemplary embodiment of the invention, another method of operating a wire bonding system is provided. The method includes the steps of: (a) forming a wire bond between (i) a portion of wire and (ii) a bonding location of a workpiece using a wire bonding tool; (b) raising the wire bonding tool above the wire bond after step (a); and (c) detecting if the portion of wire separates from a wire supply during at least one of step (a) and step (b).

According to other embodiments of the invention, the method recited in the immediately preceding paragraph may have any one or more of the following features: the wire bond formed in step (a) is a stitch bond of a wire loop; the wire bond formed in step (a) is a first bond of a wire loop; the wire bond formed in step (a) is a conductive bump; step (c) includes using a detection system to detect if the portion of wire separates from the wire supply during at least one of step (a) and step (b); the detection system monitors electrical continuity between the portion of wire and the wire supply during at least one of step (a) and step (b); the detection system monitors impedance between the portion of wire and the wire supply during at least one of step (a) and step (b); the detection system is electrically coupled to the wire supply such that the detection system is configured to detect if the portion of wire separates from the wire supply during at least one of step (a) and step (b); further including a step of (d) closing a wire clamp to secure another portion of wire from the wire supply if the portion of wire is separated from the wire supply during at least one of step (a) and step (b); step (d) stops the another portion of wire from being pulled through the wire bonding tool due to tension being applied to the another portion of wire; further including a step of (e) providing a wire tail with an end portion of the wire supply below a working end of the wire bonding tool after step (d); and/or step (b) includes raising the wire bonding tool above the wire bond to a tail height.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIGS. 1A-1E are a series of block diagrams illustrating a method of operating a wire bonding system in accordance with an exemplary embodiment of the invention;

FIGS. 2A-2E are another series of block diagrams illustrating another method of operating a wire bonding system in accordance with an exemplary embodiment of the invention;

FIGS. 3A-3C are another series of block diagrams illustrating yet another method of operating a wire bonding system in accordance with an exemplary embodiment of the invention; and

FIG. 4 is a flow diagram illustrating a method of operating a wire bonding system in accordance with an exemplary embodiment of the invention.

### DETAILED DESCRIPTION

In accordance with certain exemplary embodiments of the invention, methods are provided (e.g., controlled by software of a wire bonding system) for reducing the risk of a bonding wire from passing through a wire bonding tool and/or a wire clamp (a risk or phenomenon sometimes referred to as “wire fly out”) based on an electrical signal from a wire bonding system's hardware (e.g., a wire bonding machine, a ball bonding machine, etc.). For example, the methods are provided on a wire bonding system including a detection system (e.g., a BITS system, also referred to as a Bond Integrity Test System). If the detection system detects that a portion of bonded wire (e.g., a stitch bond of a wire loop, a first bond of a wire loop, a bonded bump, etc.) has prematurely separated from a wire supply on the wire bonding system (sometimes referred to as “premature termination”), a wire clamp on the wire bonding system can be closed to stop the wire (thereby preventing wire fly out). Software installed on (or accessible by) a computer system on the wire bonding system may be used to trigger the wire clamp to close when such conditions occur.

As will be appreciated by those skilled in the art, during formation of a wire bond on a wire bonding system (e.g., a ball bonding machine), there is an upward force on the wire from a tensioner (e.g., a vacuum tensioner) to provide force on the wire. This upward force may also used to seat a free air ball at a tip of a wire bonding tool (e.g., a capillary) prior to formation of a wire bond.

After certain wire bonds are formed on a wire bonding system (e.g., the stitch bond of a wire loop, a conductive bump formed using a free air ball, etc.), a wire tail may be formed. For example, after a stitch bond (e.g., a second bond) is terminated, the wire bonding tool may be raised off of the stitch bond with the wire clamp open. When the wire bonding tool reaches tail height, the wire clamp may be closed, and the wire may be torn at the stitch bond (by raising the wire bonding tool and wire clamp along the z-axis), with a wire tail extending below the tip of the wire bonding tool.

If the bonded portion of wire (e.g., the stitch bond) separates from the wire supply early during formation of the wire bond (when the wire clamp is open), the upward force created by the vacuum tensioner will remove the wire from the wire bonding tool, and the wire may pass through the wire clamp (i.e., wire fly out). This tends to create an error condition on the wire bonding system, and an operator may be needed to assist (e.g., the operator may manually rethread the wire through the wire clamp and the wire bonding tool). In order to substantially reduce the risk of wire fly out, once the early separation (termination) is detected, the wire clamp may be closed.

Thus, aspects of the invention increase the efficiency of wire bonding systems by allowing for the wire bonding system (e.g., wire bonding machine) to (i) substantially reduce wire fly out, and/or (ii) automatically form a wire tail after recovery of an early separation of a bonded portion of wire from a wire supply.

As used herein, the term “workpiece” is intended to refer to any structure configured for wire bonding. Exemplary workpieces include semiconductor elements, substrates (e.g., including a semiconductor element), an electronic component, etc.

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, etc.), a packaged semiconductor device, a flip chip semiconductor device, a die embedded in a substrate, a stack of semiconductor die, a plurality of semiconductor die on a substrate, amongst others. Further, the semiconductor element may include an element configured to be bonded or otherwise included in a semiconductor package (e.g., a spacer to be bonded in a stacked die configuration, a substrate, etc.).

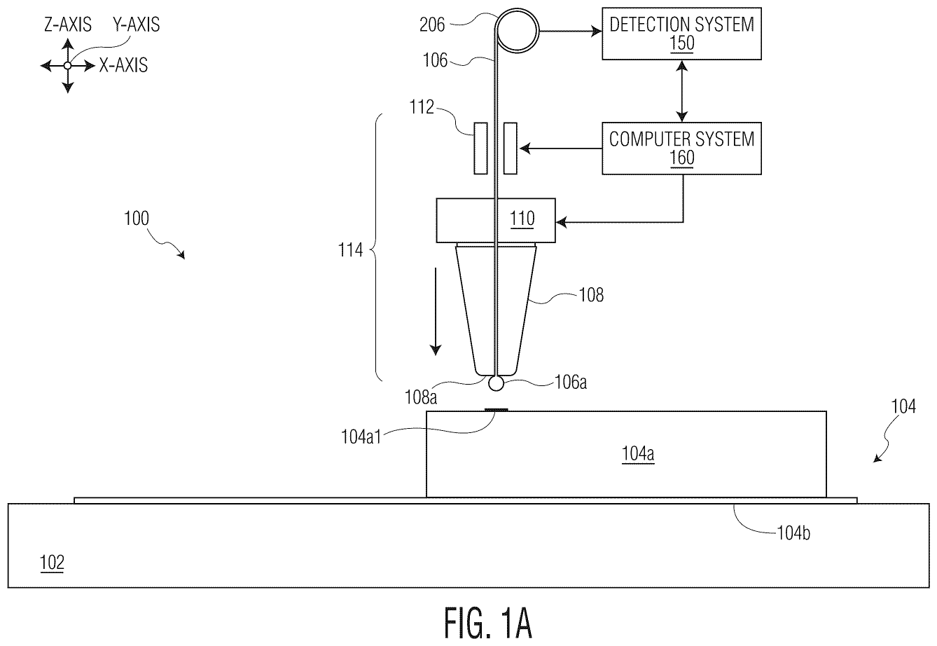

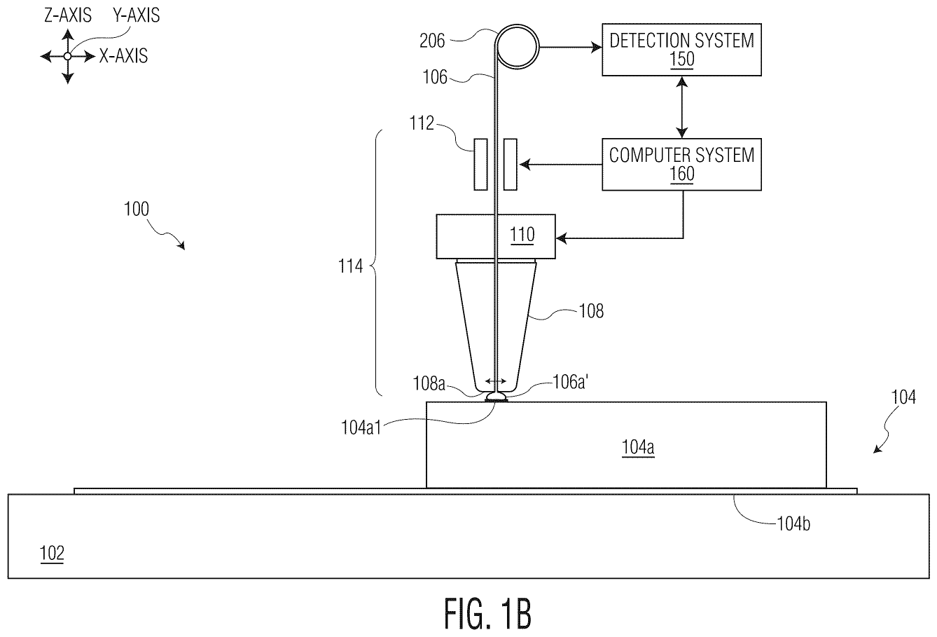

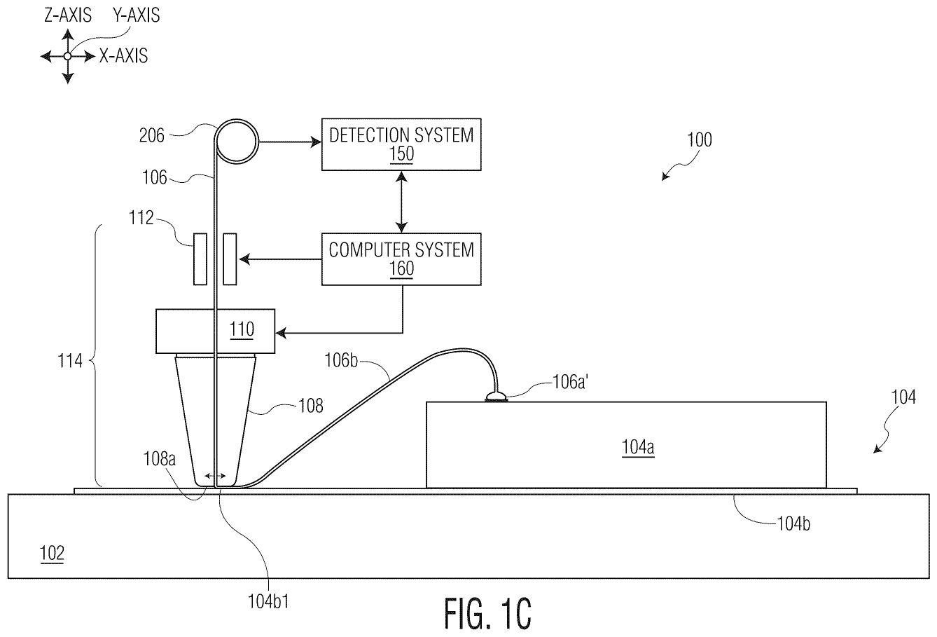

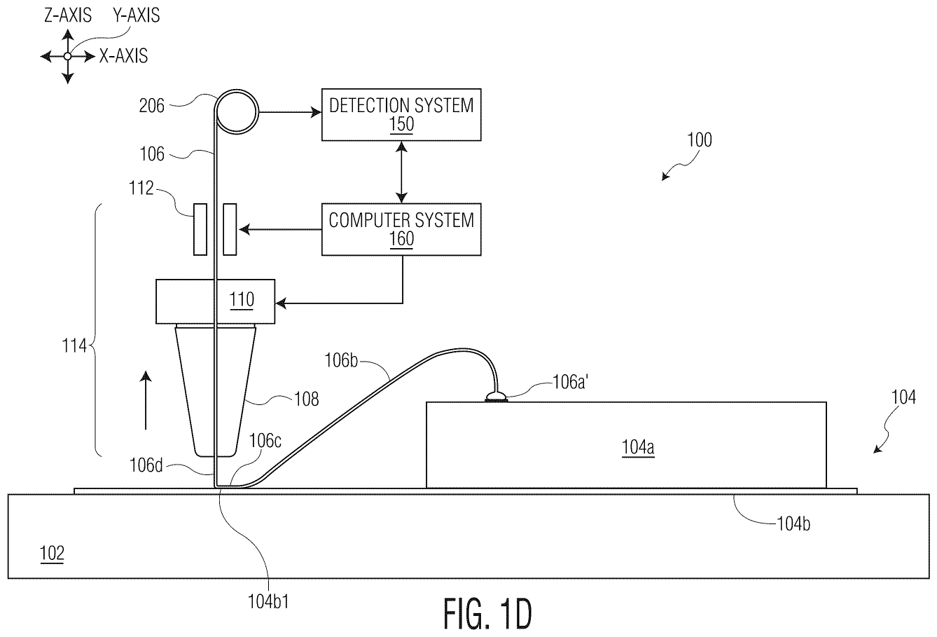

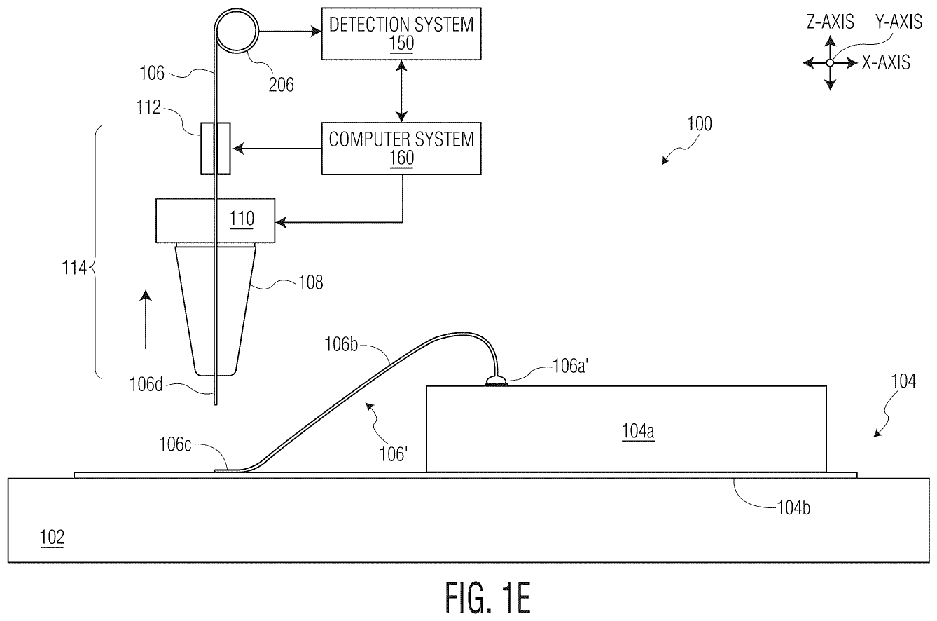

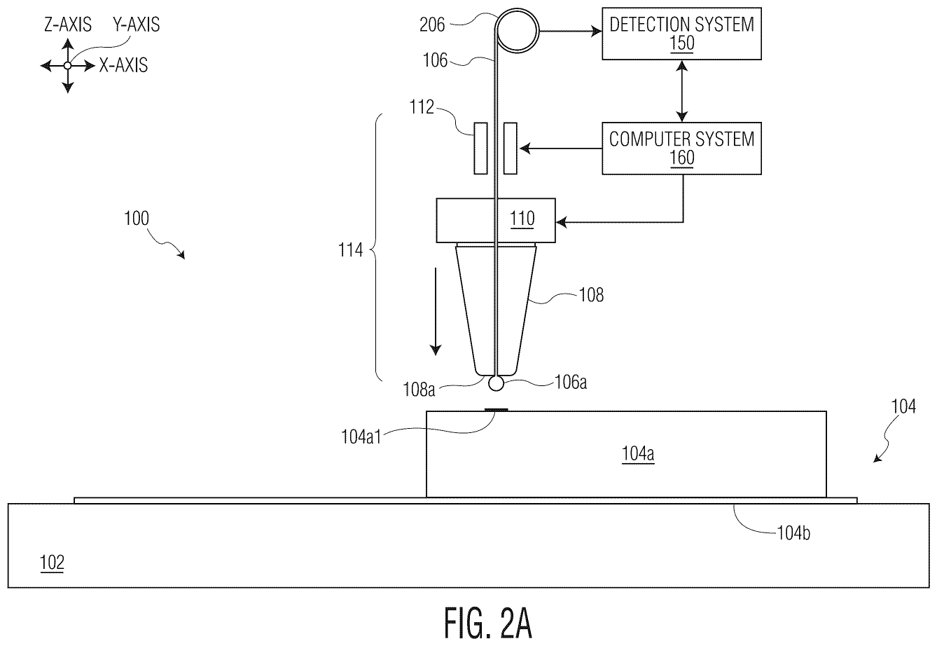

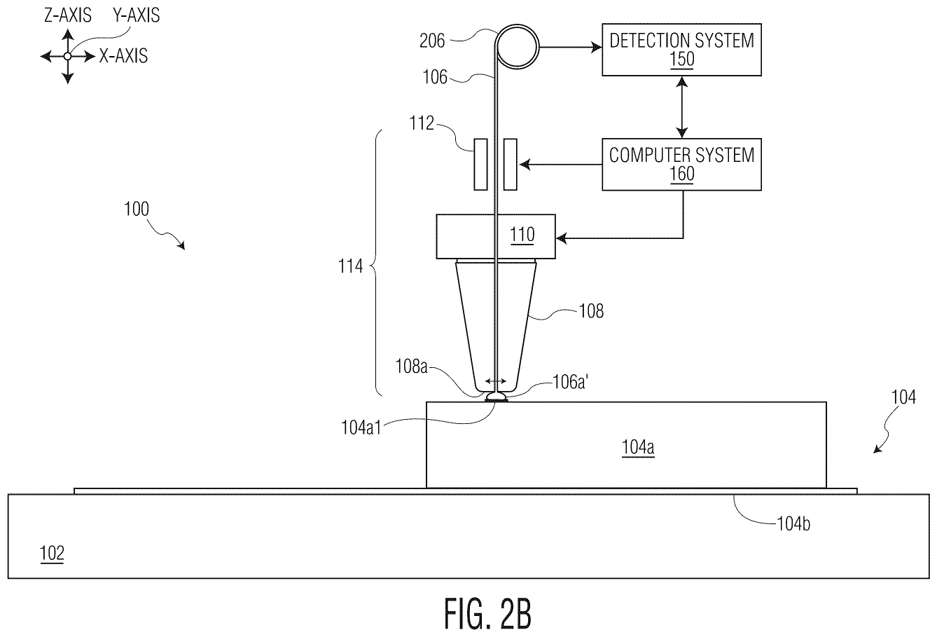

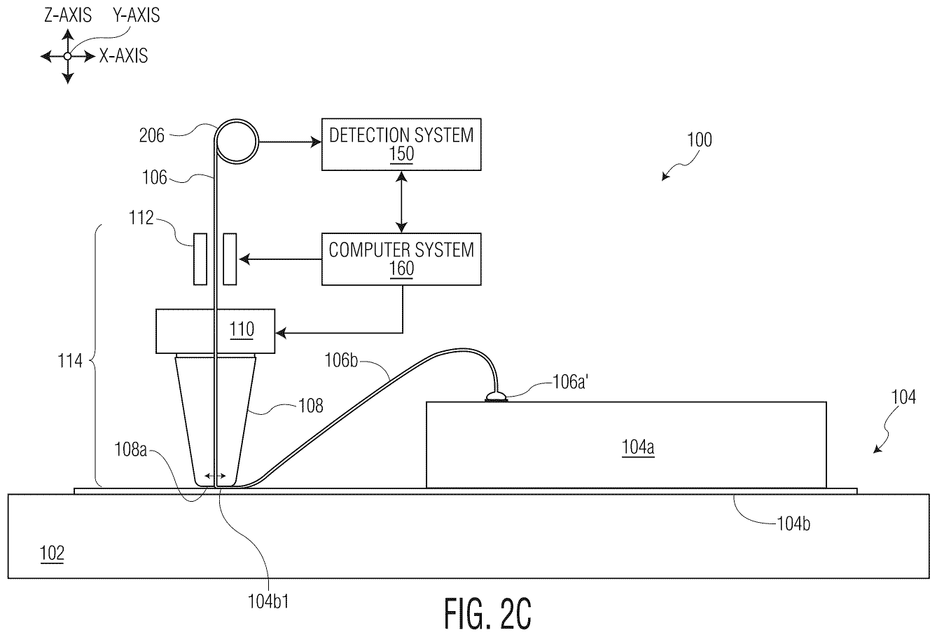

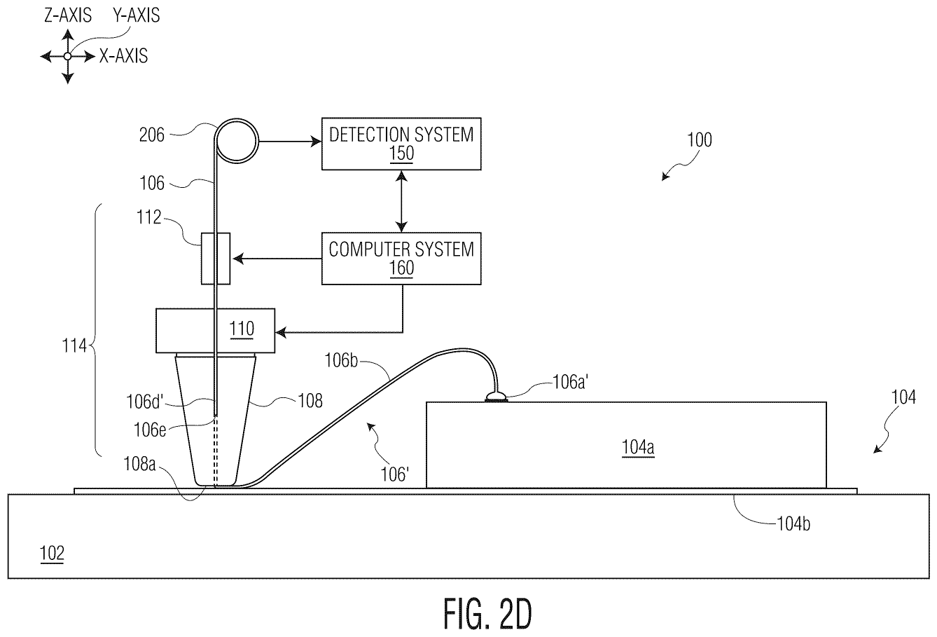

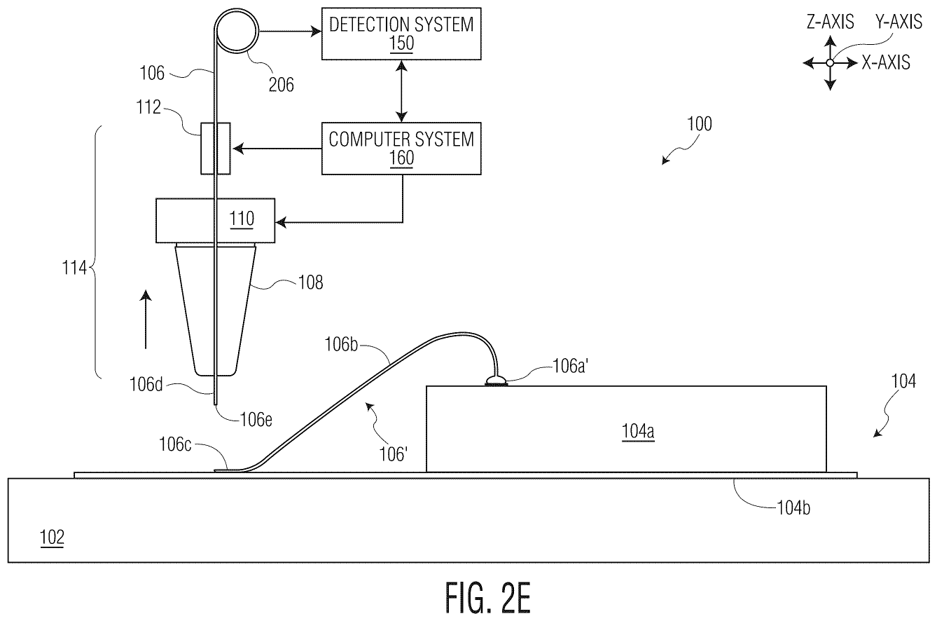

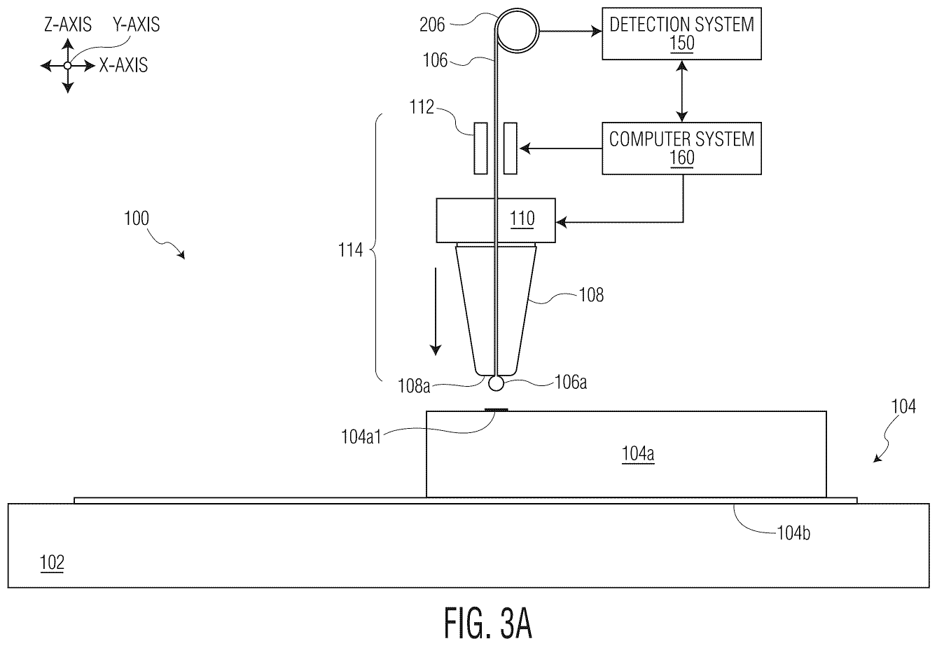

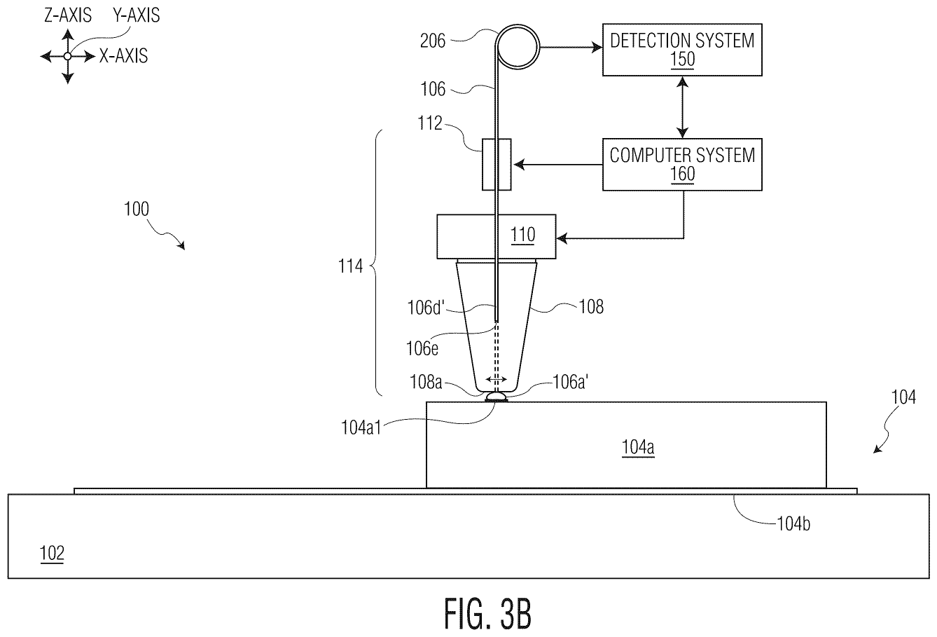

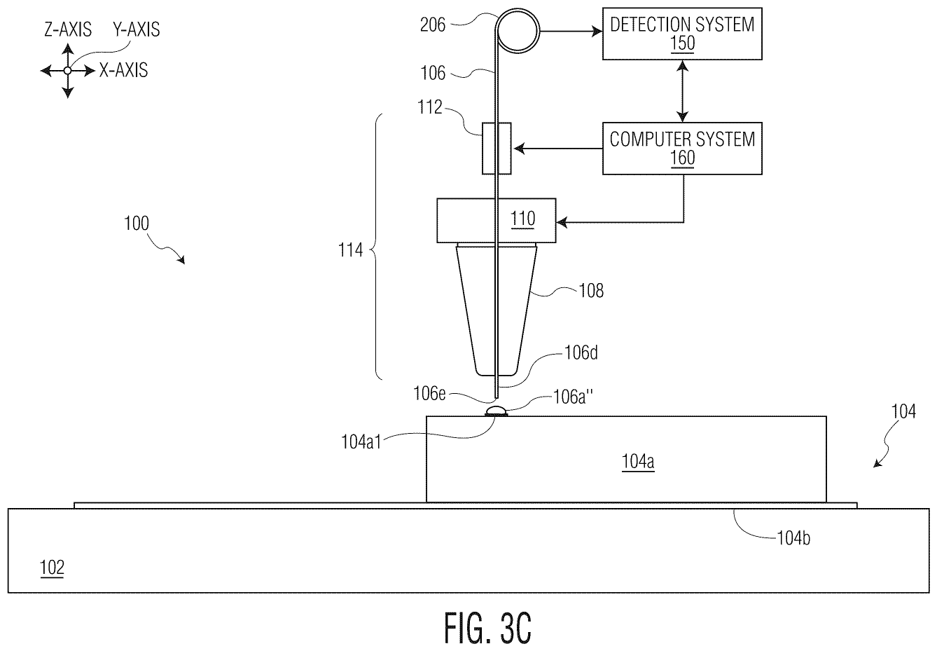

Each of FIGS. 1A-1E, FIGS. 2A-2E, and FIGS. 3A-3C illustrate a method of operating a wire bonding system (e.g., including detecting and/or preventing wire fly out). In FIGS. 1A-1E no potential wire fly out condition is detected; however, in FIGS. 2A-2E and FIGS. 3A-3C, a potential wire fly out condition is detected. The elements shown in FIGS. 1A-1E, FIGS. 2A-2E, and FIGS. 3A-3C are substantially the same, and as such, descriptions of certain of the elements are not repeated with respect to each drawing.

FIG. 1A is a block diagram side view of a wire bonding system 100. Wire bonding system 100 includes a support structure 102 (e.g., a heat block, an anvil, etc.) for supporting a workpiece 104 (e.g., a semiconductor element) during a wire bonding operation. In the illustrated example in FIG. 1A, workpiece 104 includes a semiconductor die 104a on a substrate 104b (e.g., a leadframe).

Wire bonding system 100 also includes a bond head assembly 114. Bond head assembly 114 carries (and may be considered to include) a plurality of elements such as a wire bonding tool 108, an ultrasonic transducer 110, and a wire clamp 112. Wire bonding tool 108 (e.g., a capillary, etc.) is configured to bond wire portions to workpiece 104. Wire bonding tool 108 is secured to ultrasonic transducer 110. Each of wire bonding tool 108, ultrasonic transducer 110, and wire clamp 112 is moved along a plurality of axes (e.g., the x-axis, the y-axis, and the z-axis) of wire bonding system 100 to perform wire bonding operations. Wire bonding system 100 also includes wire supply 206 (e.g., a spool of wire) to provide wire 106 for wire bonding. Wire 106 extends from wire supply 206 through wire clamp 112, and through wire bonding tool 108. A free air ball 106a is formed on an end portion of wire 106 to form a wire bond (e.g., a ball bond) on a bonding location (e.g., a bonding location 104a1) of workpiece 104.

Wire bonding system 100 also includes a computer system 160 and a detection system 150 (e.g., BITS). Computer system 160 receives data from detection system 150, and controls various elements of wire bonding system 100 (including wire clamp 112). Detection system 150 detects contact between wire 106 and bonding locations of workpiece 104. Detection system 150 may be used continuously (in any and all phases of a wire looping process) to detect if any part of a wire loop (including any bonded portion of wire) separates prematurely from wire supply 206. For example, detection system 150 may detect such contact by detecting electrical continuity, changes in impedance, etc. Data from detection system 150 (e.g., a “contact” or “no contact” status) is provided to computer system 160. Details related to exemplary detection systems are disclosed in U.S. Pat. No. 9,165,842 (e.g., see description of detection system 116), which is hereby incorporated by reference.

In the illustrated embodiments provided herein, detection system 150 is electrically coupled to wire supply 206 such that detection system 150 can detect if a bonded portion of wire separates from wire supply 206 during (or shortly after) formation of a wire bond. As will be appreciated by those skilled in the art, detection system 150 may be electrically coupled to additional and/or different parts of wire bonding system 100 to detect the separation of a bonded portion of wire from wire supply 206, all within the spirit and scope of the invention.

Still referring to FIG. 1A, free air ball 106a is provided at a working end 108a of wire bonding tool 108. More specifically, an end of wire 106 from wire supply 206 has been formed into free air ball 106a. Free air ball 106a has been seated at the tip (e.g., working end 108a) of wire bonding tool 108 using a wire tensioner (also known as a vacuum tensioner, not shown). As is understood by those skilled in the art, by seating free air ball 106a at the tip of wire bonding tool 108, free air ball 106a is in a stable position. As shown in FIG. 1A, wire bonding tool 108 is being lowered toward bonding location 104a1 (e.g., a die pad) of semiconductor element 104a.

By lowering wire bonding tool 108, free air ball 106a contacts bonding location 104a1. This contact is detected by detection system 150. Free air ball 106a is bonded (e.g., ultrasonically bonded) to first bonding location 104a1 using wire bonding tool 108. Through this bonding process, free air ball 106a is deformed and becomes bonded free air ball 106a′ (also referred to as first bond 106a′ in certain embodiments or a conductive bump in other embodiments) as shown in FIG. 1B. During (and after this bonding process), detection system 150 may be used to detect if first bond 106a′ separates from wire supply 206. If no such separation is detected, first bond 106a′ is completed, and wire bonding tool 108 is raised to extend wire in the shape of a wire loop.

FIG. 1C illustrates a condition after a length of wire 106b has been extended in the shape of a wire loop, and a second bond (e.g., a stitch bond of the wire loop, see second bond 106c in FIG. 1D) is being formed at a second bonding location 104b1. During formation of this second bond (e.g., during the ultrasonic bonding process), detection system 150 may be used to detect if second bond 106c separates from wire supply 206. If no such separation is detected, second bond 106c is completed, and wire bonding tool 108 is raised to a tail height as shown in FIG. 1D. During the raising of wire bonding tool 108 from the position shown in FIG. 1C to the tail height position shown in FIG. 1D, detection system 150 may be used to detect if second bond 106c separates from wire supply 206. If no such separation is detected, wire clamp 112 is closed, and bond head assembly 114 is raised upward to separate second bond 106c (now part of a completed wire loop 106′) from wire supply 206 as shown in FIG. 1E. As shown in FIG. 1E, a wire tail 106d is provided below the tip (i.e., working end 108a) of wire bonding tool 108. Wire tail 106d is typically then used to form another free air ball. Through the process, wire loop 106′ has been formed including first bond 106a′ (bonded to first bonding location 104a1), length of wire 106b, and second bond 106c (bonded to second bond location 104b1).

Thus, FIGS. 1A-1E illustrate a method of using detection system 150 to detect early separation of a bonded portion of wire (e.g., first bond 106a′, second bond 106c) from wire supply 206—where such early separation does not occur. In contrast, FIGS. 2A-2E illustrate detection system 150 being used to detect an actual early separation of a bonded portion of wire (i.e., second bond 106c) from wire supply 206.

Referring now to FIG. 2A, free air ball 106a is provided at a working end 108a of wire bonding tool 108. At FIG. 2B, free air ball 106a has been bonded (e.g., ultrasonically bonded) to first bonding location 104a1 using wire bonding tool 108. Through this bonding process, free air ball 106a has been deformed and becomes bonded free air ball 106a′ (also referred to as first bond 106a′) as shown in FIG. 2B. During (and after) this bonding process, detection system 150 may be used to detect if first bond 106a′ separates from wire supply 206. If no such separation is detected, first bond 106a′ is completed, and wire bonding tool 108 is raised to extend wire in the shape of a wire loop.

FIG. 2C illustrates a condition after a length of wire 106b has been extended in the shape of a wire loop, and a second bond (e.g., a stitch bond of the wire loop) is formed at a second bonding location 104b1. During formation of this second bond (e.g., during the ultrasonic bonding process), detection system 150 may be used to detect if the second bond 106c separates from wire supply 206. If no such separation is detected, second bond 106c is completed, and wire bonding tool 108 is raised toward a tail height. During the raising of wire bonding tool 108 from the position shown in FIG. 2C toward a tail height position, detection system 150 has detected that second bond 106c is separated from wire supply 206. As shown in FIG. 2D, an end of wire 106d′ is separated from second bond 106c (and is being pulled upward by vacuum tension) at break point 106e. Upon detection system 150 detecting the separation in FIG. 2D, computer system 160 caused closure of wire clamp 112, thereby avoiding a wire fly out condition. Now, a coordinated series of movements of wire bonding tool 108 (and operations of wire clamp 112), a wire tail 106d (ending at break point 106e) is provided below the tip (i.e., working end 108a) of wire bonding tool 108, as illustrated in FIG. 2E. For example, techniques disclosed in U.S. Pat. No. 9,165,842 may be used to provide an appropriate wire tail.

FIGS. 2A-2E illustrate one example of early separation of a bonded portion of wire (i.e., second bond 106c) from wire supply 206 (i.e., separation occurring after formation of second bond 106c, during the process of raising wire bonding tool 108 to “tail height”). However, the invention may be used to detect such early separation at various times during formation of a wire loop (or a conductive bump), for example: (i) during formation of first bond 106a′, (ii) while forming a wire loop shape, (iii) during formation of second bond 106c, (iv) after formation of second bond 106c, and/or (v) during the ascent of wire bonding tool 108 to the tail height.

FIGS. 1A-1E and FIGS. 2A-2E relate to formation of wire loops on wire bonding systems. Wire bonding systems are also used to form conductive bumps (sometimes referred to as “stud” bumps) with portions of wire. FIGS. 3A-3C illustrate a method of operating a wire bonding system configured for forming conductive bumps. Referring now to FIG. 3A, free air ball 106a is provided at a working end 108a of wire bonding tool 108. At FIG. 3B, free air ball 106a is in a process of being bonded (e.g., ultrasonically bonded) to first bonding location 104a1 using wire bonding tool 108. During (and after) this bonding process, detection system 150 may be used to detect if the free air ball being bonded to first bonding location 104a1 separates prematurely (before completion of the conductive bump, and formation of a wire tail) from wire supply 206. As shown in FIG. 3B, detection system 150 has detected that the partially bonded free air ball 106a (now labelled as bonded portion 106a″) is separated from wire supply 206. As shown in FIG. 3B, an end of wire 106d′ is separated from bonded portion 106a′ (and is being pulled upward by vacuum tension) at break point 106e. Upon detection system 150 detecting the separation in FIG. 3B, computer system 160 caused closure of wire clamp 112, thereby avoiding a wire fly out condition. Now, a coordinated series of movements of wire bonding tool 108 (and operations of wire clamp 112), a wire tail 106d (ending at break point 106e) is provided below the tip (i.e., working end 108a) of wire bonding tool 108, as illustrated in FIG. 3C. For example, techniques disclosed in U.S. Pat. No. 9,165,842 may be used to provide an appropriate wire tail.

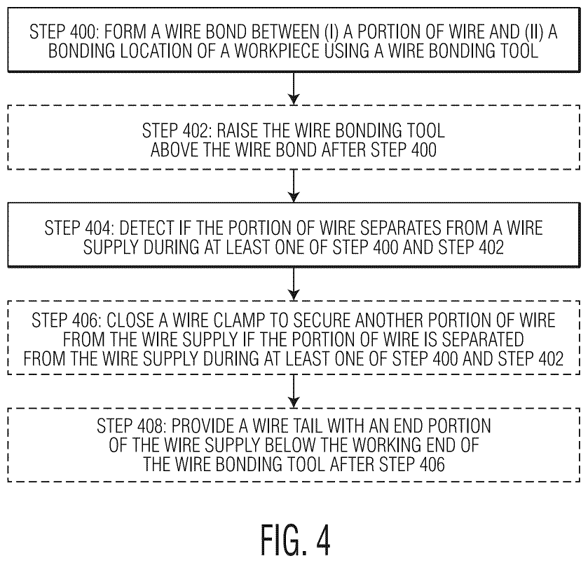

FIG. 4 is a flow diagram in accordance with certain exemplary embodiments of the present invention. As is understood by those skilled in the art, certain steps included in the flow diagram may be omitted; certain additional steps may be added; and the order of the steps may be altered from the order illustrated.

FIG. 4 is a flow diagram illustrating a method of operating a wire bonding system in accordance with an exemplary embodiment of the present invention. At Step 400, a wire bond (e.g., a stitch bond of a wire loop, a conductive bump, etc.) is formed between (i) a portion of wire and (ii) a bonding location of a workpiece using a wire bonding tool. For example, see the second bond being formed in each of FIG. 1C and FIG. 2C, or the conductive bump being formed in FIG. 3B. At optional Step 402, the wire bonding tool is raised above the wire bond after Step 400. For example, each of FIGS. 1D and 2D illustrate wire bonding tool 108 being raised above the wire bond.

At Step 404, a determination is made to detect if the portion of wire (used to form the wire bond in Step 400) separates from a wire supply during at least one of Step 400 and Step 402. For example, in FIG. 1C, detection system 150 has detected that there is no separation between the wire bond being formed (i.e., second bond 106c) and wire supply 206. Likewise, in FIG. 1D (showing wire bonding tool 108 being raised to tail height), detection system 150 has detected that there is no separation between the wire bond that has been formed (i.e., second bond 106c) and wire supply 206. In another example, in FIG. 2D (while wire bonding tool 108 is being raised toward tail height), detection system 150 has detected that there is separation between the wire bond that has been formed (i.e., second bond 106c) and wire supply 206. In another example, in FIG. 3B, detection system 150 has detected that there is separation between the portion of wire bonded to a bonding location (i.e., bonded portion 106a″) and wire supply 206.

In certain embodiments, the detection system monitors electrical continuity and/or impedance between the portion of wire and the wire supply during Step 400, Step 402, and/or Step 404. The detection system may be electrically coupled to the wire supply such that the detection system is configured to detect if the portion of wire separates from the wire supply during step Step 400, Step 402, and/or Step 404.

At optional Step 406, a wire clamp is closed to secure another portion of wire from the wire supply if the portion of wire is separated from the wire supply during at least one of Step 400 and Step 402. That is, the wire clamp is closed if it is detected that the portion of wire (used to form the wire bond in Step 400) separates from a wire supply during at least one of Step 400 and Step 402. For example, as shown in FIG. 2D, because the second bond is separated from wire supply 206, wire clamp 112 has been closed to prevent wire fly out. In another example, as shown in FIG. 3B, because bonded portion 106a″ is separated from wire supply 206, wire clamp 112 has been closed to prevent wire fly out.

In certain embodiments, Step 406 stops the another portion of wire from being pulled through the wire bonding tool due to tension being applied to the another portion of wire. At optional Step 408, a wire tail is formed with an end portion of the wire supply below the working end of the wire bonding tool after Step 406.

Although the present invention has been described primarily with respect to a wire bond of a wire loop (e.g., a second bond or stitch bond of a wire loop), it is not limited thereto. The teachings of the invention may be applicable to determining if a bonded wire portion separates from a wire supply in other instances—such as, in connection with formation of a conductive bump using a wire bonding system (as shown in FIGS. 3A-3C).

As explained herein, a wire clamp may be closed if it is detected that a portion of wire (used to form a wire bond) separates from a wire supply (i) during formation of a wire bond and/or (ii) during the process of raising the wire bonding tool above the wire bond after formation of the wire bond. It is understood that the wire clamp is open during formation of the wire bond (e.g., during application of ultrasonic energy), and during the raising of the wire bonding tool above the wire bond. Thus, the wire clamp is open, but ready to close, if the separation (e.g., early termination) is detected.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method of operating a wire bonding system, the method comprising the steps of:
(a) forming a wire bond between (i) a portion of wire and (ii) a bonding location of a workpiece using a wire bonding tool; and
(b) detecting if the portion of wire separates from a wire supply during step (a).

2. The method of claim 1 wherein the wire bond formed in step (a) is a stitch bond of a wire loop.

3. The method of claim 1 wherein the wire bond formed in step (a) is a first bond of a wire loop.

4. The method of claim 1 wherein the wire bond formed in step (a) is a conductive bump.

5. The method of claim 1 wherein step (b) includes using a detection system to detect if the portion of wire separates from the wire supply during step (a).

6. The method of claim 5 wherein the detection system monitors electrical continuity between the portion of wire and the wire supply during step (b).

7. The method of claim 5 wherein the detection system monitors impedance between the portion of wire and the wire supply during step (b).

8. The method of claim 5 wherein the detection system is electrically coupled to the wire supply such that the detection system is configured to detect if the portion of wire separates from the wire supply during step (a).

9. The method of claim 1 further comprising a step of (c) closing a wire clamp to secure another portion of wire from the wire supply if the portion of wire is separated from the wire supply during step (a).

10. The method of claim 9 wherein step (c) stops the another portion of wire from being pulled through the wire bonding tool due to tension being applied to the another portion of wire.

11. The method of claim 9 wherein further comprising a step of (d) providing a wire tail with an end portion of the wire supply below a working end of the wire bonding tool after step (c).

12. A method of operating a wire bonding system, the method comprising the steps of:
(a) forming a wire bond between (i) a portion of wire and (ii) a bonding location of a workpiece using a wire bonding tool;
(b) raising the wire bonding tool above the wire bond after step (a); and
(c) detecting if the portion of wire separates from a wire supply during at least one of step (a) and step (b).

13. The method of claim 12 wherein the wire bond formed in step (a) is a stitch bond of a wire loop.

14. The method of claim 12 wherein the wire bond formed in step (a) is a first bond of a wire loop.

15. The method of claim 12 wherein the wire bond formed in step (a) is a conductive bump.

16. The method of claim 12 wherein step (c) includes using a detection system to detect if the portion of wire separates from the wire supply during at least one of step (a) and step (b).

17. The method of claim 16 wherein the detection system monitors electrical continuity between the portion of wire and the wire supply during at least one of step (a) and step (b).

18. The method of claim 16 wherein the detection system monitors impedance between the portion of wire and the wire supply during at least one of step (a) and step (b).

19. The method of claim 16 wherein the detection system is electrically coupled to the wire supply such that the detection system is configured to detect if the portion of wire separates from the wire supply during at least one of step (a) and step (b).

20. The method of claim 12 further comprising a step of (d) closing a wire clamp to secure another portion of wire from the wire supply if the portion of wire is separated from the wire supply during at least one of step (a) and step (b).

21. The method of claim 20 wherein step (d) stops the another portion of wire from being pulled through the wire bonding tool due to tension being applied to the another portion of wire.

22. The method of claim 20 wherein further comprising a step of (e) providing a wire tail with an end portion of the wire supply below a working end of the wire bonding tool after step (d).

23. The method of claim 12 wherein step (b) includes raising the wire bonding tool above the wire bond to a tail height.
